(19) United States
(12) Patent Application Publication
(10) Pub. No.: US 2005/0106869 A1
(43) Pub. Date: May 19, 2005

(54) Plasma processing apparatus

(76) Inventors: Jun Ooyabu, Yamanashi (JP); Akira Koshiishi, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/505,176

(22) PCT Filed: Mar. 10, 2003
(86) PCT No.: PCT/JP03/02773

(30) Foreign Application Priority Data
Mar. 11, 2002 (JP) 20023-65265

(51) Int. Cl. H01L 21/302; H01L 21/461

(52) U.S. Cl. 438/689

(57) ABSTRACT

A plasma processing apparatus enabling reduction of the deposition of CF polymers in a processing chamber. The plasma processing apparatus (1) comprises a plasma processing vessel (3) having a large diameter at the lower portion and a small diameter at the upper portion to define a processing chamber (2) inside the vessel. The pressure in the processing chamber (2) is reduced to a predetermined vacuum atmosphere, and a processing gas containing a CF gas is introduced into the processing chamber (2) and changed to a plasma, and thereby a semiconductor wafer (34) is subjected to a desired microprocessing. A Y₂O₃ sprayed coating (41) is formed over a predetermined area of an inner wall (3b) of the plasma processing vessel (3) so that solid particles of CF polymers produced from the decomposition components of the CF gas by the plasma may be prevented from flying and adhering to the inner wall (3b) and the surface of the parts in the processing chamber, and the CF polymers may be prevented from depositing.

### FIELD OF THE INVENTION

The present invention relates to a plasma processing apparatus.

### BACKGROUND OF THE INVENTION

A plasma processing apparatus, e.g., a plasma etching processing apparatus has been used for performing microprocessing on the surface of a semiconductor wafer or the like as an object to be processed in a semiconductor fabrication process.

A conventional plasma etching processing apparatus includes a processing vessel into which an etching reaction gas is introduced; and, as in-chamber components, an upper electrode and a lower electrode are disposed facing and parallel to each other inside the processing vessel. The semiconductor wafer is placed on the lower electrode and etched by a radical species produced by dissociation of the etching reaction gas by a plasma, which is excited by applying a high frequency power to the lower electrode and generated between the upper and lower electrodes. In general, the lower electrode is made of aluminum and the upper electrode is made of carbon.

As a material for the inner wall of the processing vessel or in-chamber components, Al₂O₃ (alumina) ceramic, SiO₂, Qz (quartz), C (carbon), or the like, has been used. As a processing gas introduced into the processing vessel, a CF (fluorocarbon) based gas has been used widely. In this case, on the inner wall surface of the processing vessel or on the surfaces of the in-chamber components, a CF based polymer, which is a reaction byproduct resulting from plasma processing of the CF based gas, is produced.

A deposition formed by accumulation of such a CF based polymer is scattered after being peeled off as a particle from the inner wall of the processing vessel and adheres to the semiconductor wafer, which is the object to be processed, resulting in yield deterioration.

In order to suppress accumulation of the deposition, the inner wall of the processing vessel is heated up to 200 to 300° C., or the frequency of regular cleaning for the inner wall is increased to remove the deposition.

However, heating of the inner wall of the processing vessel up to 200 to 300° C. entails significantly enlarging the processing apparatus to accommodate a heat insulating structure, increased power consumption for heating, and higher costs. Further, increasing the frequency of regular cleaning cycle is problematic given that it would demand additional workforce and more time therefor.

It is, therefore, an object of the present invention to provide a plasma processing apparatus capable of reducing the accumulation of CF based polymer deposition in the processing vessel.

### SUMMARY OF THE INVENTION

In accordance with the present invention for achieving the aforementioned object, there is provided a plasma processing apparatus including: a processing vessel in which a plasma therein is excited to perform microprocessing on a surface of an object to be processed; and in-chamber components disposed inside the processing vessel, wherein at least one of surfaces of the processing vessel's inner wall and the in-chamber components is coated with an Y₂O₃ sprayed coating over a predetermined area.

Here, it is preferable that the predetermined area is greater than or equal to a surface area [S(m²) ] satisfying the following equation, S=6.554 A/(t×5×10⁶), wherein A is a gas flow rate (sccm) in the processing vessel and t is a thickness (m) of the Y₂O₃ sprayed coating.

Further, it is more preferable that the predetermined area is greater than or equal to 0.65 m².

Still further, it is more preferable that the predetermined area is greater than or equal to 0.91 m².

Meanwhile, it is preferable that the in-chamber components contain at least one of an upper and a lower electrode.

It is preferable that the plasma processing apparatus is used for a contact process.

Further, it is more preferable that the plasma processing apparatus is used for a self-alignment contact process.

### BRIEF DESCRIPTION OF THE DRAWINGS

FIG. 1 shows a schematic configuration of a plasma processing apparatus in accordance with a preferred embodiment of the present invention.

FIG. 2 is a graph illustrating a relationship between the surface area of an inner wall 3b on which an Y₂O₃ sprayed coating 41 in FIG. 1 is formed and the flow rate of a CF based gas.

FIG. 3 shows a graph illustrating a relationship between the number of particles in the processing chamber 2 in FIG. 1 and the application time of a high frequency power from a high frequency power source 27.

### DETAILED DESCRIPTION OF THE PREFERRED EMBODIMENT

As a result of the research in the following case conducted by the prevent inventors to achieve the above objective, it has been discovered that with respect to a plasma processing apparatus including a processing vessel in which a plasma therein is excited to perform microprocessing on the surface of an object to be processed, and in-chamber components disposed inside the processing vessel, if at least one of the surfaces of the processing vessel's inner wall and the in-chamber components is coated with an Y₂O₃ sprayed coating over a predetermined area, preferably 0.65 m² or greater, and more preferably 0.91 m² or greater, it is possible to react the Y₂O₃ sprayed coating with a CF based polymer, thereby reducing the accumulation of CF based polymer deposition in the processing chamber.

Further, the present inventors have discovered that if the surface of the upper or the lower electrode is coated with the Y₂O₃ sprayed coating, it is possible to effectively react the Y₂O₃ sprayed coating with the CF based polymer, thereby reducing effectively the accumulation of CF based polymer deposition in the processing chamber.

The present invention is based on the above research results.

Hereinafter, a plasma processing apparatus in accordance with a preferred embodiment of the present invention will be described in detail with reference to the accompanying drawings.

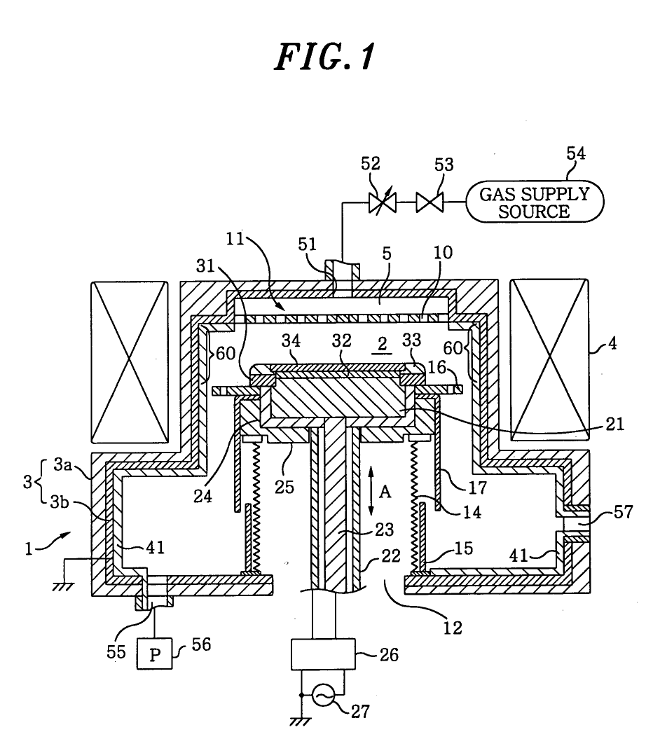

FIG. 1 shows a schematic configuration of a plasma processing apparatus in accordance with a preferred embodiment of the present invention.

As shown in FIG. 1, a plasma etching processing apparatus 1 includes a plasma processing vessel 3 having a large diameter at the lower portion and a small diameter at the upper portion to form a processing chamber 2 therein. The upper portion of the plasma processing vessel 3 is surrounded by an annular permanent magnet 4.

The plasma processing vessel 3 has a downward recessed portion 5 in the inner side of the top portion and an opening 12 in the central portion of the bottom portion. The plasma processing vessel 3 has a two-layered structure formed of its outer wall 3a made of alumina treated aluminum and its inner wall 3b made of Al₂O₃ ceramic.

In the plasma processing vessel 3, the recessed portion 5 of the top portion is isolated by an upper electrode 11 in which multiple holes are formed, and the opening 12 of the bottom portion is isolated by a gas exhaust ring 16 and the like through a bellows 14 made of a conductive material, e.g., stainless or the like, which is vertically installed from the corresponding bottom portion. The bellows 14 is protected by a first bellows cover 15 vertically installed from the bottom portion of the plasma processing vessel 3 and a second bellows cover 17 fixed on the gas exhaust ring 16 so that it fits in the first bellows cover 15.

The gas exhaust ring 16 has a lower electrode 21 in its central portion, and in the lower surface of the lower electrode 21, there is fixed an elevating shaft 23 extending from the bottom portion of the plasma processing vessel 3. Further, the elevating shaft 23 is accommodated in a tube-shaped member 22 made of a conductive material, e.g., oxidized Al or the like, and it raises and lowers the lower electrode 21 in A direction as shown in the drawing. The lower electrode 21's lower and side surfaces are protected by an electrode protection member 24 of which lower and side surfaces are coated with a conductive member 25. A high frequency power source 27 is connected to the elevating shaft 23 via the matching unit 26.

Around the top surface of the lower electrode 21, an insulator ring 31 is disposed, and an electrostatic chuck 32 is disposed on the top surface of the lower electrode 21 and on the inner side of the insulator ring 31. Further, a focus ring 33 is disposed on the insulator ring 31, and a semiconductor wafer as an object to be processed is mounted on the electrostatic chuck 32, in the inner side of the focus ring 33.

The in-chamber components include the upper electrode 11, the first bellows cover 15, the second bellows cover 17, the gas exhaust ring 16, the lower electrode 21, the electrode protection member 24, the insulator ring 31, the electrostatic chuck 32, and the focus ring 33.

In the top portion of the plasma processing vessel 3, a gas supply port 51 is installed, and a gas supply source 54 for supplying a processing gas into the processing chamber 2 is connected to the gas supply port 51 through a flow rate control valve 52 and an opening/closing valve 53. Further, a gas exhaust port 55 is installed in the bottom portion of the plasma processing vessel 3, and a vacuum pump 56 for vacuum exhausting the inside of the processing chamber 2 is connected to the gas exhaust port 55. In the lower and side portion of the plasma processing vessel 3, there is installed a transferring port 57 for an object to be processed for loading and unloading the semiconductor wafer 34.

Further, the surface of the plasma processing vessel 3's inner wall 3b is coated with an Y₂O₃ sprayed coating 41, and the Y₂O₃ sprayed coating 41 is grounded.

In the plasma etching apparatus 1 having a configuration as above, the elevating shaft 23 is moved in the direction of the arrow A to adjust the position of the semiconductor wafer 34 by a driving unit (not shown). From the high frequency power source 27, a high frequency power of, e.g., 13.56 MHz is applied to the lower electrode 21 via the elevating shaft 23.

Further, when the processing chamber 2 is vacuum pumped to a predetermined vacuum level by the vacuum pump 56 and when a processing gas containing a CF based gas is supplied into the processing chamber 2 from the gas supply source 54 via the gas supply port 51, a glow discharge results between the upper electrode 11 and the lower electrode 21, so that the processing gas is converted into a plasma. Consequently, a desired microprocessing is performed on the semiconductor wafer 34 on which masking has been performed. At this time, solid particles of CF polymers produced from decomposition components of the CF based gas by the plasma are scattered. However, since the surface of the plasma processing vessel 3's inner wall 3b is coated with the Y₂O₃ sprayed coating 41, the accumulations of CF based polymer's deposits on the surfaces of the inner wall 3b and the in-chamber components are prevented.

Hereinafter, a mechanism that the Y₂O₃ sprayed coating 41 suppresses the accumulation of CF based polymer's deposits in the processing chamber 2 will be described in detail.

With respect to a case in which C₄F₆, C₄F₈, and C₅F₈ are utilized as the CF based gas when performing a plasma processing, O₂ is always used together. Therefore, the deposition, which is a CF₂ polymer, is produced via reaction equations 1 to 3, as shown below.
a(C₄F₆)+b(O₂)→(CF₂)ₓ+c(COF₂)+d(CO) [reaction equation 1]
a(C₄F₈)+b(O₂)→(CF₂)ₓ+c(COF₂)+d(F₂) [reaction equation 2]
a(C₅F₈)+b(O₂)→(CF₂)ₓ+c(COF₂)+d(F₂)+e(O₂) [reaction equation 3]

Wherein X, a, b, c, d, and e are natural numbers.

A CF₂ polymer produced in such a manner reacts with Y₂O₃ coated on the inner wall 3b as the sprayed coating 41, like shown below.
(CF₂)x+f(Y₂O₃)→g(YF₃)+h(CO) [reaction equation 4]

Wherein X, f, g, and h are natural numbers.

By the reaction between CF₂ and Y₂O₃ as shown in reaction equation 4, the deposition of the CF₂ polymer can be reduced in the inner wall 3b and the in-chamber components.

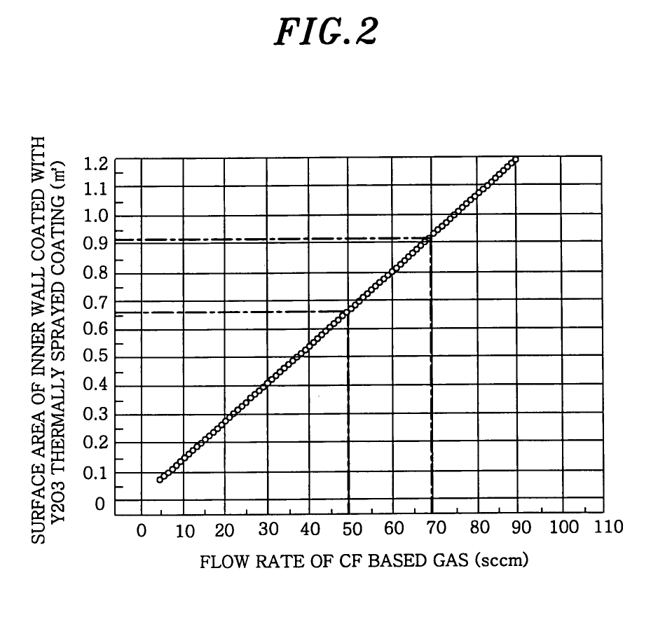

FIG. 2 is a graph for showing a relationship between the surface area of the inner wall 3b coated with the Y₂O₃ sprayed coating 41 in FIG. 1 and the flow rate of the CF based gas.

A relational expression on which the graph of FIG. 2 is based is obtained as discussed below.

When a flow rate A(sccm) [sccm is a volumetric flow rate (cm³/min) at a reference temperature, and A(sccm) is equal to A×₁₀⁻⁶ (m³/min)] of the CF based gas running through the processing chamber 2 is, i.e., 7.44×10⁻⁷ A(mol/sec), a CF based gas corresponding to 20% of the CF based gas flow rate, i.e., 7.44×10⁻⁷ A×0.2=1.49×10⁻⁷ A(mol/sec), is left in the processing chamber 2, based on a relation between the exhausting capacity of the vacuum pump 56 and a mass flow corresponding to F included in CF based gas running through the processing chamber 2.

Further, given that the ratio of ‘a’ to the degree of polymerization (X) of the CF₂ polymer is 2 in reaction equations 1 to 3 and the ratio of ‘f’ to the degree of polymerization (X) of the CF₂ polymer is 3 in reaction equation 4 even if all of CF based gas is converted into the CF₂ polymer, the moles of Y₂O₃ sprayed coating 41 required per unit time are 1.49×0.66=9.92×10⁻⁸ A(mol/sec) corresponding to 66% (2×1/3) of the moles corresponding to the flow rate of the CF based gas remaining in the processing chamber 2.

Further, the deposition ratio of the CF₂ polymer to the Y₂O₃ sprayed coating 41 is represented by [surface area of sidewall 60]/[(surface areas of upper and lower electrodes 11 and 21)+(surface area of sidewall 60)]. In addition, given that the minimum ratio is 8%[distance of 20 mm between upper electrode 11 and lower electrode 21] and at least 1000 hours corresponding to a lifetime of a constituent components of the sidewall 60 is required as a lifetime of the Y₂O₃ sprayed coating 41, the moles of the Y₂O₃ sprayed coating 41 necessary to avoid the deposition of CF₂ polymer is 9.92×10⁻⁸ A×0.08×1000×3600=0.029 A(mol) Further, given that the molecular weight of Y₂O₃ is about 226, the mass flow of the Y₂O₃ sprayed coating 41 necessary to avoid the deposition of the CF₂ polymer is 0.029 A×226=6.554 A(g).

Further, given that the thickness of the Y₂O₃ sprayed coating 41 is 1×10⁻⁴ (m) and the specific gravity of Y₂O₃ is 5×10⁶ (g/m²), the surface area (S) of the inner wall 3b coated with the Y₂O₃ sprayed coating 41 is S=6.554 A/(1×10⁻⁴×5×10⁶) (m³) and a relational expression of FIG. 2, i.e., S=0.0131 A (m²) is obtained.

As shown in FIG. 2, in case of an apparatus for a semiconductor wafer having a diameter of about 200 mm or less, given that the maximum flow rate of CF based gas is about 50 sccm, it is preferable that the surface area of the inner wall 3b coated with the Y₂O₃ sprayed coating 41 is 0.65 m² or greater.

Further, in case of an apparatus for a semiconductor wafer having a diameter of about 300 mm or less, given that the maximum flow rate of the CF based gas is about 70 sccm, it is preferable that the surface area of the inner wall 3b coated with the Y₂O₃ sprayed coating 41 is 0.91 m² or greater.

In accordance with the preferred embodiment, since the Y₂O₃ sprayed coating 41 is coated over a large area with respect to the area to be exposed to a plasma in the inner wall 3b of the processing chamber 2, the Y₂O₃ sprayed coating 41 of the inner wall 3b can be reacted with the CF based polymer. Therefore, the deposition of the CF based polymer inside the processing chamber 2 can be reduced.

In the present embodiment, the surface of the inner wall 3b is coated with the Y₂O₃ sprayed coating 41, but it is not limited thereto. If the surfaces of the in-chamber components, particularly, the upper electrode 11 and the lower electrode 21 which convert the CF based gas into a plasma, are coated with the Y₂O₃ sprayed coating 41, CF based polymers produced can be reacted further effectively with Y₂O₃, thereby reducing effectively the deposition of CF based polymers in the processing chamber 2.

Further, in the present embodiment, a plasma etching processing apparatus 1 having a magnetic field assist type, in which a permanent magnet 4 is disposed in the outer periphery of the plasma processing vessel 3, is used as an example, but it is not limited thereto. It is obvious that similarly, the present embodiment may be applied to a plasma etching processing apparatus 1 of another type, e.g., an ion assist type, in which a plasma is produced by applying high frequency powers to both of the upper and the lower electrode 11 and 21, without installing the permanent magnet 4.

Hereinafter, a comparative study result of a relationship between the number of particles within the processing chamber 2 and an application time of a high frequency power from the high frequency power source 27 will be shown with respect to cases of employing the plasma etching processing apparatus 1 in accordance with the present invention wherein the inner wall 3b of the plasma processing vessel 3 is coated with the Y₂O₃ sprayed coating 41, and employing a conventional plasma etching processing apparatus.

This study is conducted in the following manner: a turbo molecular pump having an exhaust rate of 1.3 m²/sec is used as a vacuum pump 56; and the surface of the inner wall 3b of the processing chamber 2 is coated with the Y₂O₃ sprayed coating 41 over a surface area of 0.7 m².

In this embodiment, a GND potential part of the processing chamber 2, i.e., the inner wall 3b is configured to be coated with the Y₂O₃ sprayed coating 41, but it is preferable that at least a processing space between the upper electrode 11 and the lower electrode 21, and a neighboring GND potential part, i.e., the vicinity of the sidewall 60, are coated with the Y₂O₃ sprayed coating 41.

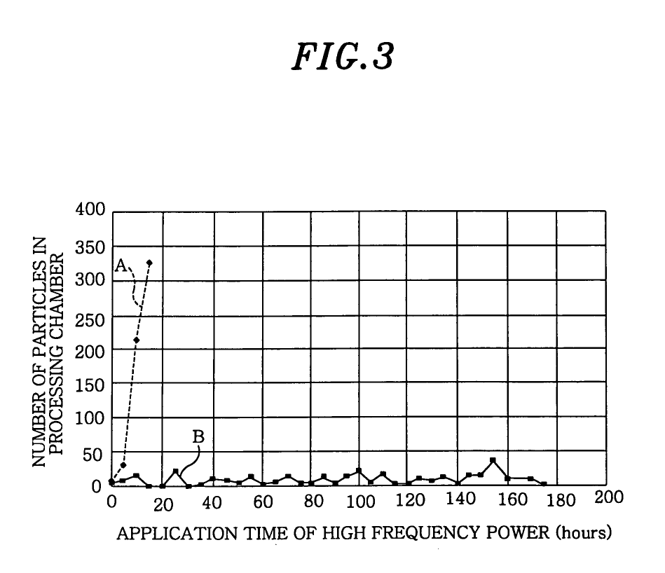

FIG. 3 is a graph which illustrates a relationship between the number of particles within the processing chamber 2 in FIG. 1 and an application time of a high frequency power from the high frequency power source 27.

In FIG. 3, a broken line A is for a case of a conventional plasma etching processing apparatus, and a solid line B is for a case of the plasma etching processing apparatus 1 in accordance with the present invention wherein the inner wall 3b is coated with the Y₂O₃ sprayed coating 41.

As indicated by the broken line A, in case of the conventional plasma etching processing apparatus, the number of particles suddenly increases with respect to the application time of the high frequency power, so that the number of particles becomes about 30 after 5 hours, about 220 after 10 hours, and about 330 after 15 hours. Although no measurement was made after 15 hours, the number of particles is expected to increase even further.

In contrast, as indicated by the solid line B in case of the plasma etching processing apparatus 1 in accordance with the present invention wherein the inner wall 3b is coated with the Y₂O₃ sprayed coating 41, the number of particles does not increase with respect to the application time of the high frequency power. Further, the number of particles is less than substantially 20 over 175 hours and is suppressed to less than 40 as the maximum value.

As shown by the comparative result, it can be demonstrated that the number of particles in the processing chamber 2 becomes less, that is, the deposition of the CF based polymer can be reduced in the inner wall 3b and the in-chamber components, by coating the inner wall 3b of the processing chamber 2 with the Y₂O₃ sprayed coating 41.

Further, in the plasma etching processing apparatus 1 of the present invention, a period for performing the next regular cleaning can be extended from 30 hours (prior interval) to 150 hours.

Further, in case of using a large scale turbo molecular pump having a high exhaust rate, e.g., 2.2 m²/sec, it is possible to immediately discharge from the processing chamber 2 CF based fine depositions, decomposed CO, or the like, which are suspended in the processing chamber 2, without remaining therein. Therefore, the depositions of CF based polymers can be further reduced in the processing chamber 2.

In case of employing the aforementioned plasma etching processing apparatus 1 of the present invention for a contact process, particularly, a self-alignment contact process, CO produced by reaction equation 4 deactivates an active fluoride radical (F₂), which is produced when the CF based gas is dissociated by a plasma, thereby enhancing the selectivity with respect to SiN (silicon nitride) and base Si (silicon).

[Industrial Applicability]

As mentioned above in detail, in accordance with a plasma processing apparatus of the present invention, since at least one of the surfaces of a processing vessel's inner wall and in-chamber components is coated with an Y₂O₃ sprayed coating over a predetermined area, the Y₂O₃ sprayed coating can be reacted with CF based polymers. Therefore, the deposition of the CF based polymer in the processing chamber can be reduced.

Further, since the predetermined area is equal to or greater than a surface area [S (m²)] satisfying S=6.554 A/(t×5×10⁶), the accumulation of the CF based polymer deposition in the processing chamber can be reduced for sure.

Still further, since the predetermined area is equal to or greater than 0.65 m², in a case where the apparatus is used for an object having a diameter of about 200 mm or less, the deposition of the CF based polymer in the processing chamber can be reduced certainly.

Still further, since the predetermined area is equal to or greater than 0.91 m², in a case where the apparatus is used for an object having a diameter of about 300 mm or less, the accumulation of the CF based polymer deposition in the processing chamber can be reduced certainly.

Still further, since the in-chamber components are formed of at least one of the upper and the lower electrodes, the Y₂O₃ sprayed coating can be reacted effectively with the CF based polymer. Therefore, the accumulation of CF based polymer deposition in the processing chamber can be reduced effectively.

Still further, as a result of being used for a contact process, the selectivity with respect to silicon nitride and base silicon can be enhanced.

1. A plasma processing apparatus comprising:
a processing vessel in which a plasma therein is excited to perform microprocessing on a surface of an object to be processed; and
in-chamber components disposed inside the processing vessel,
wherein at least one of surfaces of the processing vessel's inner wall and the in-chamber components is coated with an Y₂O₃ sprayed coating over a predetermined area.

2. The plasma processing apparatus of claim 1, wherein the predetermined area is greater than or equal to a surface area [S(m²)] satisfying the following equation,
S=6.554 A/(t×5×10⁶)
wherein A is a gas flow rate (sccm) in the processing vessel and t is a thickness (m) of the Y₂O₃ sprayed coating.

3. The plasma processing apparatus of claim 2, wherein the predetermined area is greater than or equal to 0.65 m².

4. The plasma processing apparatus of claim 3, wherein the predetermined area is greater than or equal to 0.91 m².

5. The plasma processing apparatus of claim 1, wherein the in-chamber components include at least one of an upper and a lower electrode.

6. The plasma processing apparatus of claim 1, wherein the plasma processing apparatus is used for a contact process.

7. The plasma processing apparatus of claim 6, wherein the plasma processing apparatus is used for a self-alignment contact process.
